(19) United States
(12) Patent Application Publication
(10) Pub. No.: US 2020/0379039 A1
(43) Pub. Date: Dec. 3, 2020

(54) ELECTRONIC COMPONENT HANDLER AND ELECTRONIC COMPONENT TESTER

(71) Applicant: Seiko Epson Corporation, Tokyo (JP)

(72) Inventor: Yuki ARAI, Azumino (JP)

(21) Appl. No.: 16/885,387

(22) Filed: May 28, 2020

(30) Foreign Application Priority Data
May 29, 2019 (JP) 2019-100419

(51) Int. Cl. G01R 31/28

(52) U.S. Cl. CPC G01R 31/2893

(57) ABSTRACT

An electronic component handler includes a container mounting section, an electronic-component mounting section, a device conveying head configured to hold an IC device and convey the IC device between the container mounting section and the electronic-component mounting section, a position detecting section configured to detect a reference position of the device conveying head, and a control section configured to control the device conveying head. The control section calculates, based on information concerning the reference position of the device conveying head detected by the position detecting section, a teaching position of the device conveying head and, when a distance between the calculated teaching position and a stored teaching position is equal to or larger than a predetermined value, determines that the calculated teaching position is abnormal.

The present application is based on, and claims priority from JP Application Serial Number 2019-100419, filed May 29, 2019, the disclosure of which is hereby incorporated by reference herein in its entirety.

### BACKGROUND

### 1. Technical Field

The present disclosure relates to an electronic component handler, a determining method, and an electronic component tester.

### 2. Related Art

There has been known a handler that moves, with a hand, an electronic component such as an IC from a tray to a carrier or moves, with the hand, the electronic component after measurement from the carrier to the tray and classifies and stores the electronic component. However, it is likely that, after long-time operation or after maintenance, the hand holding the electronic component causes positional deviation in an operating position and an electronic component holding mistake by the hand and an electronic component conveyance mistake between the tray and the carrier occur. Accordingly, JP A-10-156639 (Patent Literature 1) discloses a method of, in order to perform position adjustment for a hand, correcting a position by placing an imitation piece of an IC in a place where the position adjustment should be performed and inserting the hand into a hole formed in the center position of the imitation piece.

However, a handler described in Patent Literature 1 can correct an operating position of the hand but cannot detect positional deviation of the hand. Therefore, the handler cannot determine whether the operating position of the hand needs to be adjusted.

### SUMMARY

An electronic component handler according to an aspect of the present disclosure is an electronic component handler that conveys an electronic component stored in a container to a testing section that tests an electric characteristic of the electronic component, the electronic component handler including: a container mounting section on which the container is mounted; an electronic-component mounting section on which the electronic component before and after the test by the testing section is mounted; a holding section configured to hold the electronic component and convey the electronic component between the container mounting section and the electronic-component mounting section; a detecting section disposed between the container mounting section and the electronic-component mounting section and configured to detect a reference position of the holding section; and a control section configured to control the holding section. The control section calculates, based on information concerning the reference position of the holding section detected by the detecting section, an operating position where the holding section holds or places the electronic component and, when a distance between the calculated operating position and an operating position stored in advance is equal to or larger than a predetermined value, determines that the calculated operating position is abnormal.

An electronic component handler according to an aspect of the present disclosure is an electronic component handler that conveys an electronic component stored in a container to a testing section that tests an electric characteristic of the electronic component, the electronic component handler including: a container mounting section on which the container is mounted; an electronic-component mounting section on which the electronic component before and after the test by the testing section is mounted; a holding section configured to hold the electronic component and convey the electronic component between the container mounting section and the electronic-component mounting section; a detecting section disposed between the container mounting section and the electronic-component mounting section and configured to detect a reference position of the holding section; and a control section configured to control the holding section. When a distance between the reference position of the holding section detected by the detecting section and a reference position of the holding section stored in advance is equal to or larger than a predetermined value, the control section determines that the detected reference position of the holding section is abnormal.

The electronic component handler may include a display section configured to display a determination result of the control section.

In the electronic component handler, the detecting section may detect the reference position of the holding section at a predetermined time interval.

The electronic component handler may adjust the operating position of the holding section based on the distance between the calculated operating position and the stored operating position.

The electronic component handler may adjust the detected reference position of the holding section to the stored reference position of the holding section.

In the electronic component handler, the detecting section may include a first detecting section, a second detecting section, and a third detecting section. When straight lines orthogonal to each other are represented as a first axis and a second axis, the first detecting section and the second detecting section may be disposed along the first axis and the first detecting section and the third detecting section may be disposed along the second axis.

A determining method according to an aspect of the present disclosure is a determining method of determining whether, in an electronic component handler including a container mounting section on which a container is mounted, an electronic-component mounting section on which an electronic component before and after a test is mounted, a holding section configured to hold the electronic component, and a detecting section configured to detect a reference position of the holding section, an operating position where the holding section holds or places the electronic component is a normal position, the determining method including: detecting the reference position of the holding section in the detecting section between the container mounting section and the electronic-component mounting section; calculating an operating position of the holding section based on information concerning the detected reference position of the holding section; comparing the calculated operating position and the operating position stored in advance; and, when a distance between the calculated operating position and the stored operating position is equal to or larger than a predetermined value, determining that the calculated operating position is abnormal.

A determining method according to an aspect of the present disclosure is a determining method of determining whether, in an electronic component handler including a container mounting section on which a container is mounted, an electronic-component mounting section on which an electronic component before and after a test is mounted, a holding section configured to hold the electronic component, and a detecting section configured to detect a reference position of the holding section, a reference position of the holding section is a normal position, the determining method including: detecting the reference position of the holding section in the detecting section between the container mounting section and the electronic-component mounting section; comparing the detected reference position of the holding section and a reference position of the holding section stored in advance; and, when a distance between the detected reference position of the holding section and the stored reference position of the holding section is equal to or larger than a predetermined value, determining that the detected reference position of the holding section is abnormal.

An electronic component tester according to an aspect of the present disclosure is an electronic component tester that tests an electronic component stored in a container, the electronic component tester including: a testing section configured to test an electric characteristic of the electronic component; a container mounting section on which the container is mounted; an electronic-component mounting section on which the electronic component before and after the test by the testing section is mounted; a holding section configured to hold the electronic component and convey the electronic component between the container mounting section and the electronic component mounting section; a detecting section disposed between the container mounting section and the electronic-component mounting section and configured to detect a reference position of the holding section; and a control section configured to control the holding section. The control section calculates, based on information concerning the reference position of the holding section detected by the detecting section, an operating position where the holding section holds or places the electronic component and, when a distance between the calculated operating position and an operating position stored in advance is equal to or larger than a predetermined value, determines that the calculated operating position is abnormal.

An electronic component tester according to an aspect of the present disclosure is an electronic component tester that tests an electronic component stored in a container, the electronic component tester including: a testing section configured to test an electric characteristic of the electronic component; a container mounting section on which the container is mounted; an electronic-component mounting section on which the electronic component before and after the test by the testing section is mounted; a holding section configured to hold the electronic component and convey the electronic component between the container mounting section and the electronic component mounting section; a detecting section disposed between the container mounting section and the electronic-component mounting section and configured to detect a reference position of the holding section; and a control section configured to control the holding section. When a distance between the reference position of the holding section detected by the detecting section and a reference position of the holding section stored in advance is equal to or larger than a predetermined value, the control section determines that the detected reference position of the holding section is abnormal.

### BRIEF DESCRIPTION OF THE DRAWINGS

FIG. 1 is a schematic perspective view showing the configuration of an electronic component tester according to a first embodiment.

FIG. 2 is a schematic plan view showing an operation state of the electronic component tester.

FIG. 3 is a perspective view of a device conveying head.

FIG. 4 is a diagram of the device conveying head viewed from an arrow A direction in FIG. 3.

FIG. 5 is a perspective view of a position detecting section set in the electronic component tester.

FIG. 6 is a schematic horizontal sectional view showing a position detecting operation for the device conveying head in order.

FIG. 7 is a schematic horizontal sectional view showing the position detecting operation for the device conveying head in order.

FIG. 8 is a schematic partial vertical sectional view of a state shown in FIG. 7.

FIG. 9 is a schematic horizontal sectional view showing the position detecting operation for the device conveying head in order.

FIG. 10 is a schematic partial vertical sectional view of a state shown in FIG. 9.

FIG. 11 is a schematic horizontal sectional view showing the position detecting operation for the device conveying head in order.

FIG. 12 is a schematic horizontal sectional view showing the position detecting operation for the device conveying head in order.

FIG. 13 is a schematic horizontal sectional view showing the position detecting operation for the device conveying head in order.

FIG. 14 is a schematic horizontal sectional view showing the position detecting operation for the device conveying head in order.

FIG. 15 is a flowchart during initial setting.

FIG. 16 is a schematic plan view for explaining teaching positions.

FIG. 17 is a flowchart during teaching position error detection.

FIG. 18 is a diagram for explaining a detection result displayed on a display section.

FIG. 19 is a flowchart during position error detection for a holding section according to a second embodiment.

FIG. 20 is a schematic plan view showing the configuration of an electronic component tester according to a third embodiment.

### DESCRIPTION OF EXEMPLARY EMBODIMENTS

An electronic component handler, a determining method, and an electronic component tester according to an embodiment are explained in detail below based on preferred embodiments shown in the accompanying drawings.

### First Embodiment

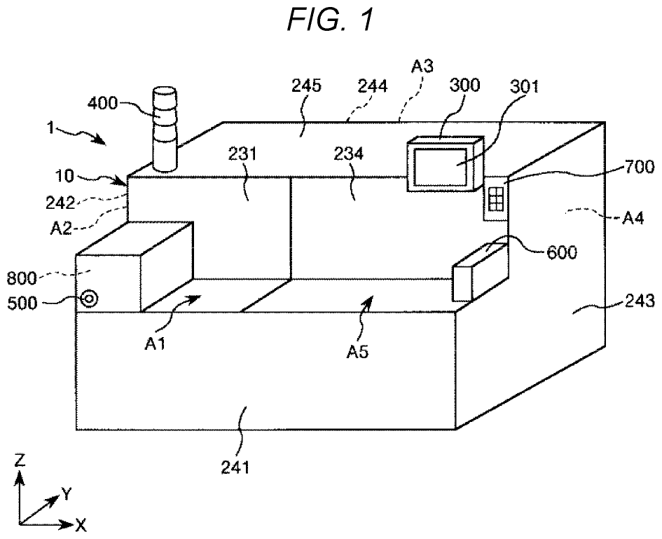

An electronic component handler, a determining method, and an electronic component tester according to a first embodiment are explained with reference to FIGS. 1 to 18. In the following explanation, for convenience of explanation, as shown in FIG. 1, three axes orthogonal to one another are represented as an X axis, a Y axis, and a Z axis. An XY plane including the X axis and the Y axis is horizontal. The Z axis is vertical. A direction along the X axis is referred to as “X direction” as well, a direction along the Y axis is referred to as “Y direction” as well, and a direction along the Z axis is referred to as “Z direction” as well. Directions in which direction arrows face are referred to as “positive” and opposite directions of the directions are referred to as “negative”. “Horizontal” in this specification is not limited to complete horizontalness and includes a state tilted a little (for example, approximately less than 5°) with respect to the horizontal. Upper sides in FIGS. 1, 3, 4, 8, 10, and are sometimes referred to as “upper” or “upward” and lower sides in FIGS. 1, 3, 4, 8, 10, and 18 are sometimes referred to as “lower” or “downward”.

### Electronic Component Tester

First, the electronic component tester and the electronic component handler according to the first embodiment are explained with reference to FIGS. 1 to 5.

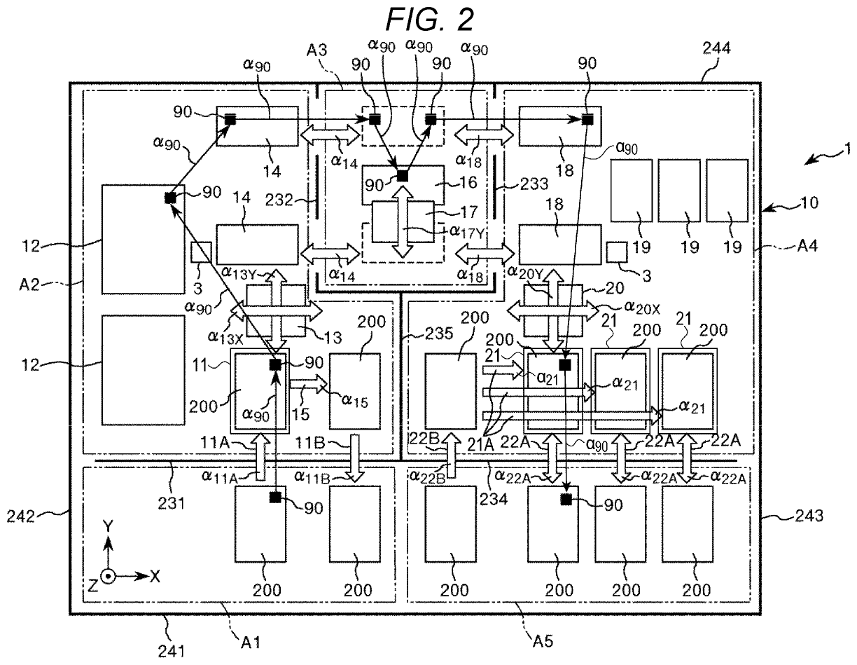

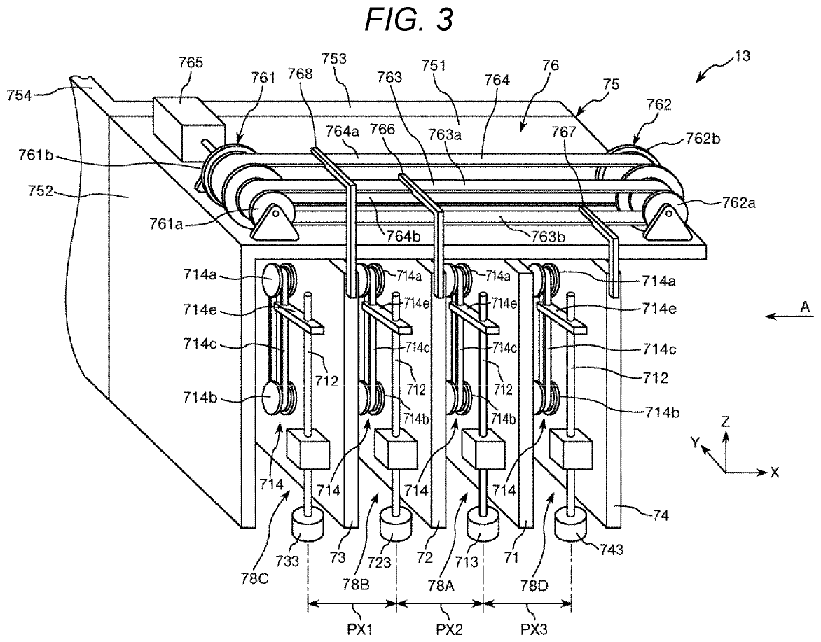

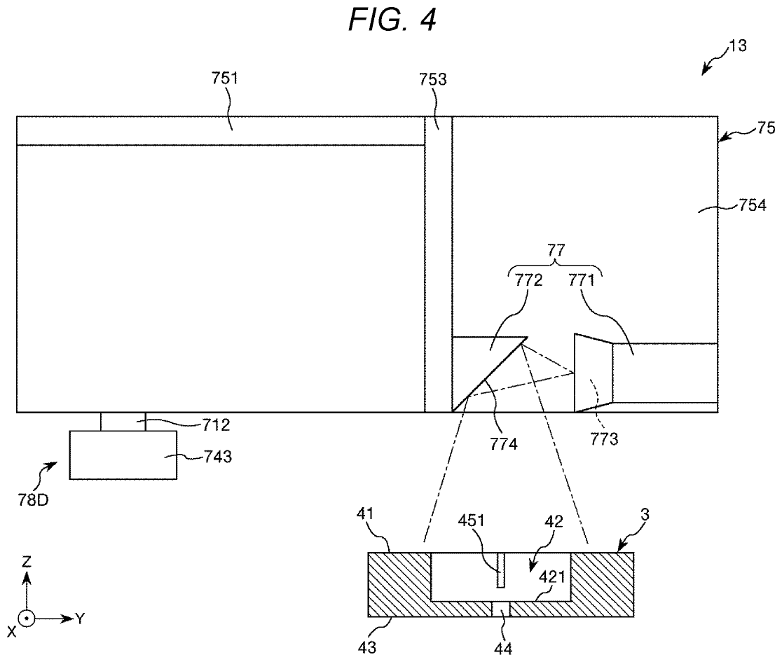

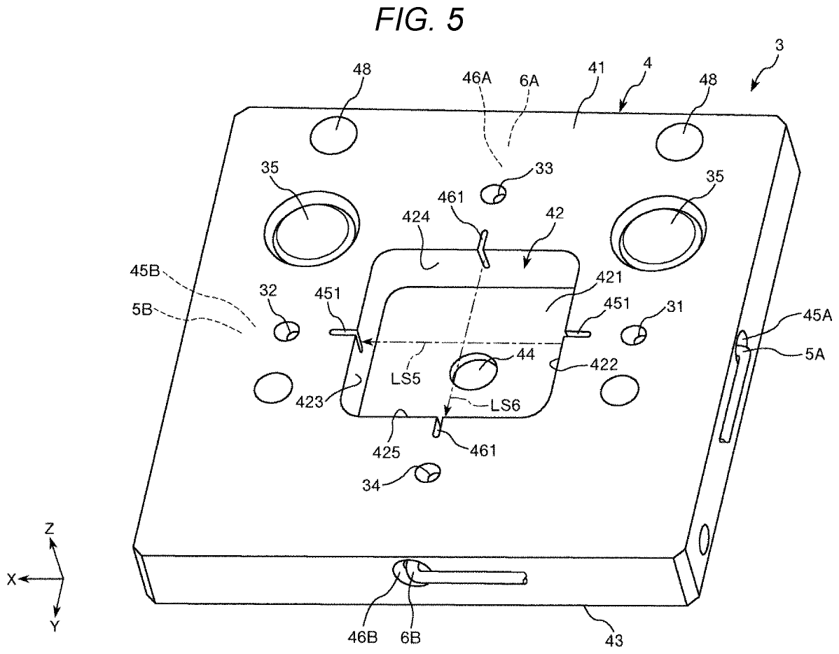

FIG. 1 is a schematic perspective view showing the configuration of the electronic component tester according to the first embodiment. FIG. 2 is a schematic plan view showing an operation state of the electronic component tester. FIG. 3 is a perspective view of a device conveying head. FIG. 4 is a diagram of the device conveying head viewed from an arrow A direction in FIG. 3. FIG. 5 is a perspective view of a position detecting section set in the electronic component tester.

As shown in FIGS. 1 and 2, an electronic component tester 1 incorporating an electronic component handler 10 is an apparatus that conveys an electronic component such as an IC device, which is a BGA (Ball Grid Array) package, and tests and examines (hereinafter simply referred to as “tests”) an electric characteristic of the electronic component in a process of the conveyance. In the following explanation, for convenience of explanation, use of the IC device as the electronic component is representatively explained. The IC device is represented as an “IC device 90”. In this embodiment, the IC device 90 is formed in a rectangular shape or a square shape in a plan view.

The electronic component tester 1 is used while being mounted with, in advance, a what is called “change kit” replaced for each type of the IC device 90. The change kit includes a shuttle on which the IC device 90 is placed. As the shuttle, there are, for example, a temperature adjusting section 12 and an electronic-component mounting section 14.

As the shuttle on which the IC device 90 is placed, separately from the change kit, there is, for example, a tray 200 functioning as a container that stores the IC device 90 prepared by a user. The tray 200 is also mounted on a container mounting section 11 of the electronic component tester 1. The tray 200 mounted on the container mounting section 11 is used, for example, when the IC device 90, which is the electronic component, is loaded in the electronic component tester 1. Consequently, a plurality of IC devices 90 in an untested state can be loaded in a tray supply region A1 explained below together with the tray 200. Accordingly, an operator can easily perform the loading work. The tray 200 is also used when the IC device 90 classified according to a test result is placed.

The electronic component tester 1 includes a tray supply region A1, a device supply region A2, a test region A3, a device collection region A4, and a tray removal region A5. These regions are partitioned by wall sections as explained below. The IC device 90 is conveyed through the tray supply region A1 to the tray removal region A5 in order in an arrow α90 direction. The IC device 90 is tested in the test region A3 halfway in the conveyance. In this way, the electronic component tester 1 includes a handler, which is the electronic component handler 10 that conveys the IC device 90 in the tray supply region A1, the device supply region A2, the device collection region A4, and the tray removal region A5, a testing section 16 that performs a test in the test region A3, and a control section 800. Besides, the electronic component tester 1 includes a monitor 300, a signal lamp 400, and an operation panel 700.

When the electronic component tester 1 is used, a side where the tray supply region A1 and the tray removal region A5 are arranged, that is, the lower side in FIG. 2 is a front side of the electronic component tester 1 and a side where the test region A3 is arranged, that is, the upper side in FIG. 2 is a rear side of the electronic component tester 1.

The tray supply region A1 is a material supply section to which the tray 200, on which a plurality of IC devices 90 in an untested state are arrayed, is supplied. In the tray supply region A1, a large number of trays 200 can bs stacked.

The device supply region A2 is a region where the plurality of IC devices 90 on the tray 200 conveyed from the tray supply region A1 and mounted on the container mounting section 11 are respectively conveyed and supplied to the test region A3. Tray conveying mechanisms 11A and 11B that convey one tray 200 at a time in the horizontal direction are provided across the tray supply region A1 and the device supply region A2. The tray conveying mechanism 11A can move the tray 200 to the positive side of the Y direction, that is, in an arrow α11A direction in FIG. 2 together with each of the IC devices 90 placed on the tray 200. Consequently, the IC device 90 can be stably fed into the device supply region A2. The tray conveying mechanism 11B can move an empty tray 200 to the negative side of the Y direction, that is, in an arrow α11B direction in FIG. 2. Consequently, the empty tray 200 can be moved from the device supply region A2 to the tray supply region A1.

In the device supply region A2, the container mounting section 11, the temperature adjusting section 12, a device conveying head 13 functioning as a holding section, the electronic-component mounting section 14, and a tray conveying mechanism 15 are provided.

The container mounting section 11 is a mounting section on which the tray 200 conveyed in from the tray supply region A1 by the tray conveying mechanism 11A is mounted.

The temperature adjusting section 12 is called “soak plate” on which the plurality of IC devices 90 are placed and the placed IC devices 90 can be collectively heated or cooled. With this soak plate, it is possible to heat or cool, in advance, the IC device 90 before being tested by the testing section 16 and adjust the temperature of the IC device 90 to temperature suitable for a high-temperature test or a low-temperature test, which is the test. In the configuration shown in FIG. 2, two temperature adjusting sections 12 are disposed and fixed in the Y direction. The IC device 90 on the tray 200 conveyed into the container mounting section 11 from the tray supply region A1 by the tray conveying mechanism 11A is conveyed to any one of the temperature adjusting sections 12. The temperature adjusting section 12 functioning as a shuttle is fixed. Therefore, the temperature adjusting section 12 can stably perform temperature adjustment on the IC device 90 on the temperature adjusting section 12.

The device conveying head 13 is supported movably in the X direction and the Y direction in the device supply region A2 and further includes a portion movable in the Z direction as well. Consequently, the device conveying head 13 can perform conveyance of the IC device 90 between the tray 200 conveyed onto the container mounting section 11 from the tray supply region A1 and the temperature adjusting section 12 and conveyance of the IC device 90 between the temperature adjusting section 12 and the electronic-component mounting section 14 explained below. In FIG. 2, movement in the X direction of the device conveying head 13 is indicated by an arrow α13X and movement in the Y direction of the device conveying head 13 is indicated by an arrow α13Y.

The electronic-component mounting section 14 is a mounting section on which the IC device 90, the temperature of which is adjusted on the temperature adjusting section 12, is mounted. The electronic-component mounting section 14 is explained in detail below.

The tray conveying mechanism 15 is a mechanism that conveys the empty tray 200 in a state in which all the IC devices 90 are removed to the positive side of the X direction, that is, in an arrow α15 direction in the device supply region A2. After the conveyance, the empty tray 200 is returned from the device supply region A2 to the tray supply region A1 by the tray conveying mechanism 11B.

The test region A3 is a region where the IC device 90 is tested. In the test region A3, the testing section and a device conveying head 17 are provided. The electronic-component mounting section 14 that moves across the device supply region A2 and the test region A3 and an electronic-component mounting section 18 that moves across the test region A3 and the device collection region A4 are also provided.

The electronic-component mounting section 14 is configured as a shuttle on which the IC device 90, the temperature of which is adjusted by the temperature adjusting section 12, is placed. The electronic-component mounting section 14 is called “shuttle plate for supply” or simply called “supply shuttle” that can convey the IC device 90 to the vicinity of the testing section 16.

The electronic-component mounting section 14 is supported to be capable of reciprocating along the X direction, that is, an arrow α14 direction between the device supply region A2 and the test region A3. Consequently, the electronic-component mounting section 14 can stably convey the IC device 90 from the device supply region A2 to the vicinity of the testing section 16 of the test region A3. After the IC device 90 is removed by the device conveying head 17 in the test region A3, the electronic-component mounting section 14 can return to the device supply region A2 again.

In the configuration shown in FIG. 2, two electronic-component mounting sections 14 are disposed in the Y direction. The IC device 90 on the temperature adjusting section 12 is conveyed to any one of the electronic-component mounting sections 14. Like the temperature adjusting section 12, the electronic-component mounting section 14 is configured to be capable of heating or cooling the IC device 90 placed on the electronic-component mounting section 14. Consequently, the electronic-component mounting section 14 can convey the IC device 90, the temperature of which is adjusted by the temperature adjusting section 12, to the vicinity of the testing section 16 in the test region A3 while maintaining a temperature adjusted state of the IC device 90.

The device conveying head 17 holds the IC device 90 maintained in the temperature adjusted state and conveys the IC device 90 in the test region A3. “Grip” means grasping and picking up. The device conveying head 17 is supported to be capable of reciprocating in the Y direction and the Z direction in the test region A3 and is formed as a part of a mechanism called “index arm”. Consequently, the device conveying head 17 conveys the IC device 90 on the electronic-component mounting section 14, which is conveyed in from the device supply region A2, onto the testing section 16 and places the IC device 90 on the testing section 16. “Place” means separating and putting on. In FIG. 2, reciprocation in the Y direction of the device conveying head 17 is indicated by an arrow α17Y. The device conveying head 17 is supported to be capable of reciprocating in the Y direction. However, not only this, but the device conveying head 17 may be supported to be capable of reciprocating in the X direction as well.

Like the temperature adjusting section 12, the device conveying head 17 is configured to be capable of heating or cooling the held IC device 90. Consequently, a temperature adjusted state in the IC device 90 can be continuously maintained from the electronic-component mounting section 14 to the testing section 16.

The testing section 16 is configured as a shuttle on which the IC device 90, which is an electronic component, is placed and an electric characteristic of the IC device 90 is tested. In the testing section 16, a plurality of probe pins electrically coupled to a terminal section of the IC device 90 are provided. The terminal section of the IC device 90 and the probe pins are electrically coupled, that is, come into contact, whereby a test for the IC device can be performed. The test for the IC device 90 is performed based on a program stored in a test control section included in a tester coupled to the testing section 16. Like the temperature adjusting section 12, the testing section 16 can heat or cool the IC device 90 and adjust the temperature of the IC device 90 to temperature suitable for a test.

The electronic-component mounting section 18 is configured as a shuttle on which the IC device 90, for which the test is ended by the testing section 16, is placed and the IC device 90 can be conveyed to the device collection region A4. The electronic-component mounting section 18 is called “shuttle plate for collection” or simply called “collection shuttle”.

The electronic-component mounting section 18 is supported to be capable of reciprocating along the X direction, that is, an arrow α18 direction between the test region A3 and the device collection region A4. In the configuration shown in FIG. 2, like the electronic-component mounting sections 14, two electronic-component mounting sections 18 are disposed in the Y direction. The IC device 90 on the testing section 16 is conveyed to and placed on any one of the electronic-component mounting sections 18. This conveyance is performed by the device conveying head 17.

The device collection region A4 is a region where the plurality of IC devices 90, for which the test in the test region A3 ended, are collected. In the device collection region A4, a tray for collection 19, a device conveying head 20 functioning as a holding section, and a tray conveying mechanism 21A are provided. In the device collection region A4, the empty tray 200 placed on a container mounting section 21 is also prepared.

The tray for collection 19 is a shuttle on which the IC device 90 tested by the testing section 16 is placed. The tray for collection 19 is fixed not to move in the device collection region A4. Consequently, even in the device collection region A4 where a relatively large number of various movable sections such as the device conveying head 20 are disposed, the tested IC device 90 is stably placed on the tray for collection 19. In the configuration shown in FIG. 2, three trays for collection 19 are disposed along the X direction.

Three container mounting sections, 21, on which empty trays 200 are placed, are also disposed along the X direction. The container mounting sections 21, on which the empty trays 200 are placed, also function as shuttles on which the IC devices 90 tested by the testing sections 16 are placed. The IC device 90 on the electronic-component mounting section 18 moved to the device collection region A4 is conveyed to and placed on any one of the trays for collection 19 and the empty trays 200. Consequently, the IC device 90 is classified for each of test results and collected.

The device conveying head 20 is supported movably in the X direction and the Y direction in the device collection region A4 and further includes a portion movable in the Z direction as well. Consequently, the device conveying head 20 can convey the IC device 90 from the electronic component mounting section 18 to the tray for collection 19 and the empty tray 200. In FIG. 2, movement in the X direction of the device conveying head 20 is indicated by an arrow α20X and movement in the Y direction of the device conveying head 20 is indicated by an arrow α20Y.

The tray conveying mechanism 21A is a mechanism that conveys the empty tray 200, which is conveyed in from the tray removal region A5, in the X direction, that is, an arrow α21 direction in the device collection region A4. After the conveyance, the empty tray 200 is disposed in a position where the IC device 90 is collected. In other words, the empty tray 200 can be any one of the three empty trays 200.

The tray removal region A5 is a material removing section where the tray 200, on which the plurality of IC devices 90 in the tested state are arrayed, is collected and removed. In the tray removal region A5, a large number of trays 200 can be stacked.

Tray conveying mechanisms 22A and 22B, which convey one tray 200 at a time in the Y direction, are provided across the device collection region A4 and the tray removal region A5. The tray conveying mechanism 22A can cause the tray 200 to reciprocate in the Y direction, that is, an arrow α22A direction. Consequently, the tray conveying mechanism 22A can convey the tested IC device 90 from the device collection region A4 to the tray removal region A5. The tray conveying mechanism 22B can move the empty tray 200 for collecting the IC device 90 to the positive side of the Y direction, that is, in an arrow α22B direction. Consequently, the tray conveying mechanism 22B can move the empty tray 200 from the tray removal region A5 to the device collection region A4.

The control section 800 can control the operations of the tray conveying mechanism 11A, the tray conveying mechanism 11B, the temperature adjusting section 12, the device conveying head 13, the electronic-component mounting section 14, the tray conveying mechanism 15, the testing section 16, the device conveying head 17, the electronic-component mounting section 18, the device conveying head 20, the tray conveying mechanism 21A, the tray conveying mechanism 22A, and the tray conveying mechanism 22B.

The operator can set and confirm operation conditions and the like for the electronic component tester 1 via the monitor 300. The monitor 300 includes, for example, a display screen 301 functioning as a display section configured by a liquid crystal screen and is disposed above on the front side of the electronic component tester 1. As shown in FIG. 1, a mouse stand 600 for placing a mouse is provided on the right side in FIG. 1 of the tray removal region A5. The mouse is used when operating a screen displayed on the monitor 300.

The operation panel 700 is disposed in the lower right of FIG. 1 with respect to the monitor 300. The operation panel 700 is a component for, separately from the monitor 300, instructing the electronic component tester 1 to perform desired operation.

The signal lamp 400 can inform an operation state and the like of the electronic component tester 1 according to a combination of light emission colors. The signal lamp 400 is disposed in an upper part of the electronic component tester 1. A speaker 500 is incorporated in the electronic component tester 1. The operation state and the like of the electronic component tester 1 can also be informed by the speaker 500.

In the electronic component tester 1, the tray supply region A1 and the device supply region A2 are partitioned by a first partition wall 231, the device supply region A2 and the test region A3 are partitioned by a second partition wall 232, the test region A3 and the device collection region A4 are partitioned by a third partition wall 233, and the device collection region A4 and the tray removal region A5 are partitioned by a fourth partition wall 234. The device supply region A2 and the device collection region A4 are partitioned by a fifth partition wall 235.

The outermost exterior of the electronic component tester 1 is covered with covers. The covers include, for example, a front cover 241, a side cover 242, a side cover 243, a rear cover 244, and a top cover 245.

As explained above, in the device supply region A2, the device conveying head 13 is supported movably in the X direction and the Y direction. As shown in FIG. 3, the device conveying head 13 includes a base 75. The base is supported movably in the X direction and the Y direction orthogonal to the X direction.

Such a base 75 includes a first base 751, a second base 752, a third base 753, and a fourth base 754. The first base 751 is a portion formed in a tabular shape having a spread on the XY plane and having thickness in the Z direction. The second base 752 is a portion extending from the edge portion on the X-direction negative side in the downward direction on the Z-direction negative side of the first base 751 and formed in a tabular shape having a spread on a YZ plane and having thickness in the X direction. The third base 753 is a portion extending from the edge portion on the Y-direction positive side in the downward direction of the first base 751 and formed in a tabular shape having a spread on an XZ plane and having thickness in the Y direction. The fourth base 754 is a portion extending from the edge portion on the X-direction negative side to the Y-direction positive side of the third base 753 and formed in a tabular shape having a spread on the YZ plane and having thickness in the X direction.

The device conveying head 13 includes a first supporting section 71, a second supporting section 72, a third supporting section 73, and a fourth supporting section 74 supported by the base 75. These four supporting sections are provided side by side in the order of the third supporting section 73, the second supporting section 72, the first supporting section 71, and the fourth supporting section 74 from the X-direction negative side to the X-direction positive side.

The first supporting section 71, the second supporting section 72, the third supporting section 73, and the fourth supporting section 74 are respectively formed in a tabular shape having a spread on the YZ plane and having thickness in the X direction. By forming the first supporting section 71 to the fourth supporting section 74 in the tabular shape having the spread on the YZ plane in this way, it is possible to provide the first supporting section 71 to the fourth supporting section 74 in parallel in the X direction at a narrow pitch. Accordingly, it is possible to achieve a reduction in the size of the device conveying head 13.

Among these four supporting sections, the first supporting section 71 is fixed to the first base 751. The second supporting section 72, the third supporting section 73, and the fourth supporting section 74 are respectively supported by the first base 751 via not-shown linear guides and are movable in the X direction.

The device conveying head 13 includes a moving mechanism 76 that performs the movement. The moving mechanism 76 includes a two-stage pulley 761 and a two-stage pulley 762, a belt 763 and a belt 764 stretched and suspended between the two-stage pulley 761 and the two-stage pulley 762, and a motor 765 that rotates the two-stage pulley 761. The two-stage pulley 761, the two-stage pulley 762, and the motor 765 are respectively supported by the first base 751.

The two-stage pulley 761 and the two-stage pulley 762 are rotatable around axes extending in the Y direction on the upper surface of the first base 751. The two-stage pulley 761 and the two-stage pulley 762 are provided to be separated in the X direction.

The two-stage pulley 761 includes a small-diameter pulley 761a having a small outer diameter and a large-diameter pulley 761b having an outer diameter approximately twice as large as the outer diameter of the small-diameter pulley 761a. The small-diameter pulley 761a and the large-diameter pulley 761b are concentrically formed side by side in the Y direction. Similarly, the two-stage pulley 762 includes a small-diameter pulley 762a having a small outer diameter and a large-diameter pulley 762b having an outer diameter approximately twice as large as the outer diameter of the small-diameter pulley 762a. The small-diameter pulley 762a and the large-diameter pulley 762b are concentrically formed side by side in the Y direction. The outer diameters of the small-diameter pulley 761a and the small-diameter pulley 762a are equal to each other. The outer-diameters of the large-diameter pulley 761b and the large-diameter pulley 762b are also equal to each other.

The belt 763 is stretched and suspended between the small-diameter pulley 761a and the small-diameter pulley 762a. The belt 763 includes two regions 763a and 763b extending in the X direction between the small-diameter pulley 761a and the small-diameter pulley 762a. The second supporting section 72 is coupled and fixed to the region 763a via a coupling member 766. The fourth supporting section 74 is coupled and fixed to the region 763b via a coupling member 767. When the two-stage pulley 761 rotates in one direction, for example, the belt 763 advances toward the X-direction negative side in the region 763a and the belt 763 advances toward the X-direction positive side in the region 763b. Therefore, the second supporting section 72 and the fourth supporting section 74 move to the opposite sides in the X direction each other and move a substantially equal distance.

On the other hand, the belt 764 is stretched and suspended between the large-diameter pulley 761b and the large-diameter pulley 762b. The belt 764 includes two regions 764a and 764b extending in the X direction between the large-diameter pulley 761b and the large-diameter pulley 762b. Of the two regions 764a and 764b, the third supporting section 73 is coupled and fixed to, via a coupling member 768, the region 764a that advances in the same direction as the region 763a of the belt 763 when the two-stage pulley 761 rotates. Consequently, the second supporting section 72 and the third supporting section 73 move in the same side in the X direction each other. As explained above, the large-diameter pulleys 761b and 762b have an outer diameter twice as large as the outer diameter of the small-diameter pulleys 761a and 762a. Therefore, a moving distance of the third supporting section 73 is approximately twice as large as a moving distance of the second supporting section 72.

With such a configuration, when the two-stage pulley 761 is rotated by the motor 765, the second supporting section 72 and the fourth supporting section 74 move to the X-direction opposite sides each other substantially equal distances. The third supporting section 73 moves in the same direction as the second supporting section 72 a distance twice as large as the moving distance of the second supporting section 72. Therefore, with the moving mechanism 76, it is possible to collectively change a pitch PX1, which is the distance in the X direction between a suction nozzle 733 of a third holding section 78C and a suction nozzle 723 of a second holding section 78B, a pitch PX2, which is the distance in the X direction between the suction nozzle 723 and a suction nozzle 713 of a first holding section 78A, and a pitch PX3, which is the distance between the suction nozzle 713 and a suction nozzle 743 of a fourth holding section 78D.

In the base 75, the first holding section 78A that holds the IC device 90, which is the electronic component, is provided via the first supporting section 71. Similarly, the second holding section 78B that holds the IC device 90 is provided via the second supporting section 72. The third holding section 78C that holds the IC device 90 is provided via the third supporting section 73. The fourth holding section 78D that holds the IC device 90 is provided via the fourth supporting section 74. Consequently, the second holding section 78B to the fourth holding section 78D are respectively movable in the X direction with respect to the first holding section 78A.

The first holding section 78A to the fourth holding section 78D have the same configuration except that supported parts are different. Therefore, the configuration of the first holding section 78A is representatively explained.

The first holding section 78A is disposed in parallel to the Z direction. The first holding section 78A includes a shaft 712 that supports the suction nozzle 713 at the lower end portion and a driving mechanism 714 that moves the suction nozzle 713 in the Z direction via the shaft 712. In the first holding section 78A having such a configuration, the suction nozzle 713 is movable in the Z direction orthogonal to the X direction and the Y direction with respect to the base 75 together with the shaft 712 according to the operation of the driving mechanism 714. Consequently, it is possible to grip the IC device 90 by lowering the suction nozzle 713 and sucking the IC device 90 with the suction nozzle 713. The held IC 90 is tested by the testing section 16 as explained above.

The configuration of the driving mechanism 714 is not particularly limited if the driving mechanism 714 can cause the shaft 712 to reciprocate in the Z direction with respect to the first supporting section 71. However, in this embodiment, the driving mechanism 714 includes a pulley 714a and a pulley 714b, a belt 714c stretched and suspended between the pulley 714a and the pulley 714b, a fixing section 714e that couples and fixes the belt 714c and the shaft 712, and a not-shown motor that rotates the pulley 714a.

The device conveying head 13 functioning as the holding section includes, as shown in FIG. 4, a camera 771 and a mirror 772 functioning as an imaging unit 77.

The camera 771 is a CCD (Charge-Coupled Device) camera. The camera 771 is fixed to the fourth base 754 of the base 75 with a camera lens 773 facing the Y-direction negative side.

The mirror 772 is disposed on the Y-direction negative side with respect to the camera 771 and includes a mirror surface 774 that refracts a visual field direction of the camera 771 downward. Consequently, when the device conveying head 13 moves on the XY plane, the camera 771 is located, for example, above the tray 200 on the container mounting section 11, the temperature adjusting section 12, the electronic-component mounting section 14, and the like in the device supply region A2 and can image the tray 200, the temperature adjusting section 12, the electronic-component mounting section 14, and the like. The positions of the tray 200, the temperature adjusting section 12, and the like are grasped based on a captured image and stored in the control section 800. The mirror 772 is fixed to the third base 753 and the fourth base 754 of the base 75.

A position detecting section 3 functioning as a detecting section is disposed in the device supply region A2 as shown in FIG. 2. A disposition place of the position detecting section 3 is preferably as close as possible to the center of the device supply region A2 between the container mounting section 11 and the electronic-component mounting section 14. The position detecting section 3 is disposed in the device collection region A4 as well. In this way, the position detecting sections 3 are provided in the device supply region A2 and the device collection region A4. This is because the same phenomenon as the phenomenon in the device conveying head 13 in the device supply region A2 can occur in the device conveying head 20 in the device collection region A4. The phenomenon can be prevented by the position detecting section 3 in the device collection region A4. The position detecting section 3 in the device supply region A2 is representatively explained. As explained above, the electronic component tester 1 includes the device supply region A2 where the IC device 90, which is the electronic component, is conveyed to the test region A3 where the IC device 90 is tested and the device collection region A4 where the IC device 90, which is an electronic component tested in the test region A3, is collected.

The position detecting section 3 includes two guide holes for positioning 48 for positioning in the device supply region A2. These guide holes for positioning 48 are disposed be separated in the X direction as much as possible. In this positioning state, the position detecting section 3 is fixed via two bolts 35.

The position detecting section 3 detects the position of the suction nozzle 733 of the third holding section 78C. As shown in FIG. 5, the position detecting section 3 includes a main body section 4, a first light emitting section 5A, a first light receiving section 5B, a second light emitting section 6A, and a second light receiving section 6B.

The position detecting section 3 includes the main body section 4 formed in a block shape or a tabular shape and configured by a rectangular member in the plan view. The main body section 4 includes a recess 42 formed in the center of an upper surface 41, a through-hole 44 formed in a bottom 421 of the recess 42 to pierce through the main body section 4 to a lower surface 43, a first-light-emitting-section inserting section 45A formed to be opened in a sidewall section 422 of the recess 42, a first-light-receiving-section inserting section 45B formed to be opened in a sidewall section 423 of the recess 42 to be opposed to the first-light-emitting-section inserting section 45A, a second-light-emitting-section inserting section 46A formed to be opened in a sidewall section 424 of the recess 42, and a second-light-receiving-section inserting section 46B formed to be opened in a sidewall section 425 of the recess to be opposed to the second-light-emitting-section inserting section 46A. The first-light-emitting-section inserting section 45A is formed to pierce through the main body section 4 along the X direction. The first light emitting section 5A is inserted into the first-light-emitting-section inserting section 45A. The first light emitting section 5A is fixed in the first-light-emitting-section inserting section 45A by a slotted set screw 31. The first-light-receiving-section inserting section 45B is formed to pierce through the main body section 4 along the X direction. The first light receiving section 5B is inserted into the first-light-receiving-section inserting section 45B. The first light-receiving section 5B is fixed in the first-light-receiving-section inserting section 45B by a slotted set screw 32. The second-light-emitting-section inserting section 46A is formed to pierce through the main body section 4 along the Y direction. The second light emitting section 6A is inserted into the second-light-emitting-section inserting section 46A. The second light emitting section 6A is fixed in the second-light-emitting-section inserting section 46A by a slotted set screw 33. The second light-receiving-section inserting section 46B is formed to pierce through the main body section 4 along the Y direction. The second light receiving section 6B is inserted into the second light-receiving-section inserting section 46B. The second light-receiving section 6B is fixed in the second-light-receiving-section inserting section 46B by a slotted set screw 34.

All of the first light emitting section 5A, the first light receiving section 5B, the second light emitting section 6A, and the second light receiving section 6B are fiber sensors. The first light emitting section 5A can emit light LS5, which is laser light, toward the X-direction positive side, that is, the first light receiving section 5B. The first light receiving section 5B can receive the light LS5. The second light emitting section 6A can emit light LS6, which is laser light, toward the Y-direction positive side, that is, the second light receiving section 6B. The second light receiving section 6B can receive the light LS6.

In this way, the position detecting section 3 includes the first light emitting section 5A that emits the light LS5 in the X direction, the first light receiving section 5B that receives the light LS5 emitted from the first light emitting section 5A, the second light emitting section 6A that emits the light LS6 in the Y direction, and the second light receiving section 6B that receives the light LS6 emitted from the second light emitting section 6A. Consequently, as explained below, it is possible to detect the position in the X direction of the suction nozzle 733 of the third holding section 78C based on transmission and blocking of the light LS5. It is possible to detect the position in the Y direction of the suction nozzle 733 of the third holding section 78C based on transmission and blocking of the light LS6.

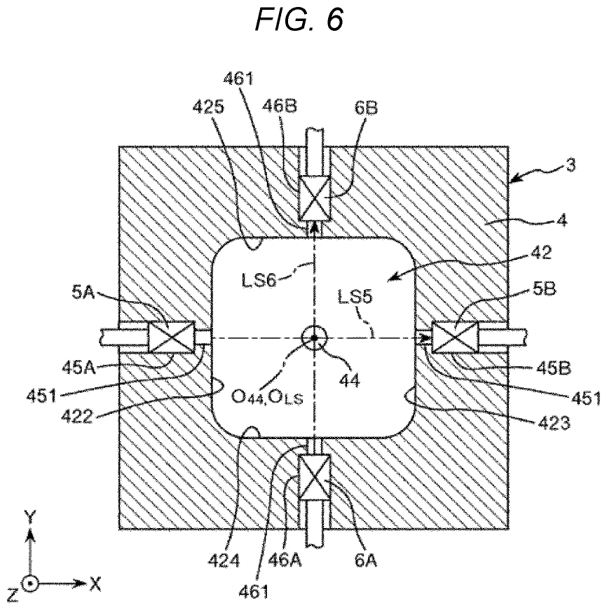

As shown in FIG. 5 and FIG. 6 referred to below, the first-light-emitting-section inserting section 45A and the first-light-receiving-section inserting section 45B respectively include slits 451. The light LS5 passes through the slits 451, whereby diffusion of the light LS5 is prevented. Accordingly, the directivity of the light LS5 is improved. The second-light-emitting-section inserting section 46A and the second-light-receiving-section inserting section 46B respectively include slits 461. The light LS6 passes through the slits 461, whereby diffusion of the light LS6 is prevented. Accordingly, the directivity of the light LS6 is improved.

In the position detecting section 3, the through-hole 44 is a portion smaller than the bottom 421 in the plan view. As shown in FIG. 4, the through-hole 44 functions as a recognition mark to be imaged by the camera 771. With this recognition mark, a coordinate of the device conveying head 13 at the time when a center O44 of the through-hole formed in a circular shape in the plan view and the imaging center of the camera 771 coincide can be set as an XY coordinate of the imaging center of the camera 771. The portion functioning as the recognition mark may be, instead of the through-hole 44, a projection formed to project on the bottom 421 and smaller than the bottom 421 in the plan view.

As shown in FIG. 6 referred to below, the center O44 of the through-hole 44 is disposed in a position overlapping an intersection OLS of the light LS5 and the light LS6 in the plan view. Consequently, XY coordinates of the center of the suction nozzle 733 disposed in this position and the imaging center of the camera 771 are calculated based on an XY coordinate of the device conveying head 13. Therefore, a difference between respective positions of the device conveying head 13 at the time when the center of the suction nozzle 733 is disposed in the same XY coordinate and at the time when the imaging center of the camera 771 is disposed in the same XY coordinate is calculated as a difference in an XY coordinate between the center of the suction nozzle 733 and the imaging center of the camera 771. In other words, a relative positional relation, that is, a distance between the center of the suction nozzle 733 attached to the base 75 of the device conveying head 13 and the imaging center of the camera 771 attached to the base 75 is calculated from a moving position of the device conveying head 13.

Detection of the position of the suction nozzle 733 of the third holding section 78C is explained with reference to FIGS. 6 to 14.

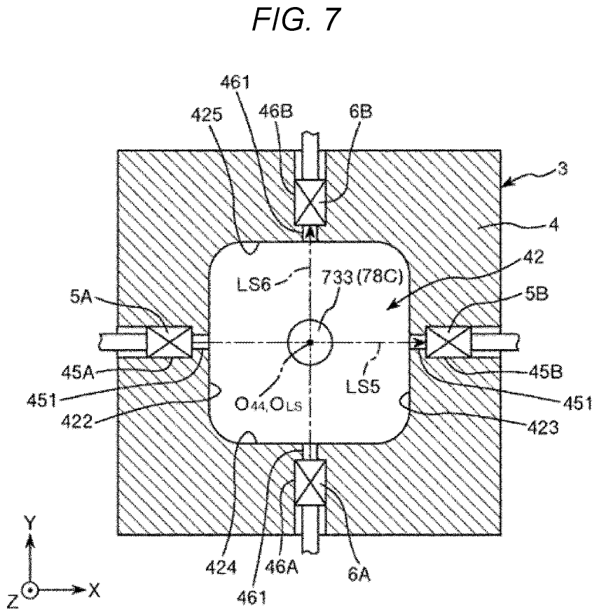

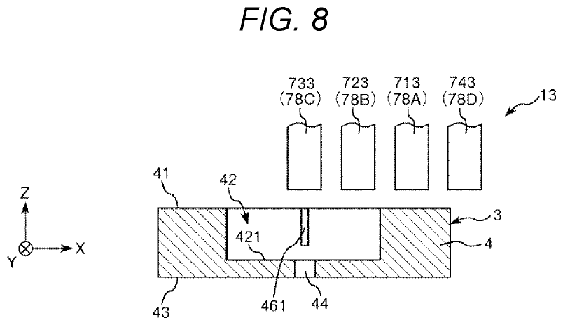

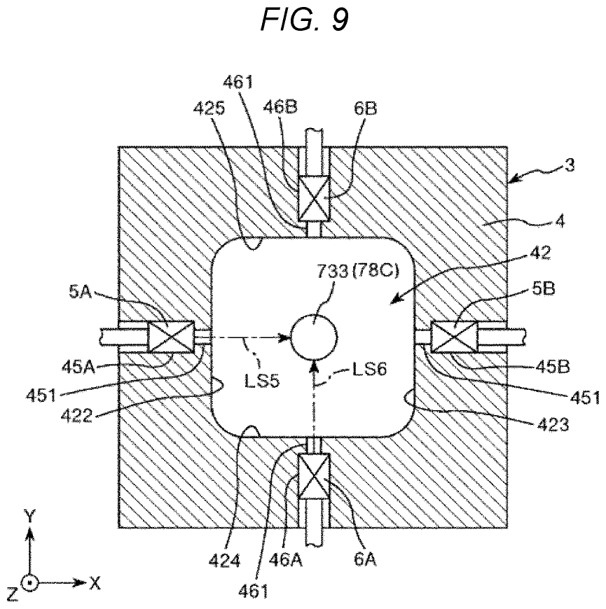

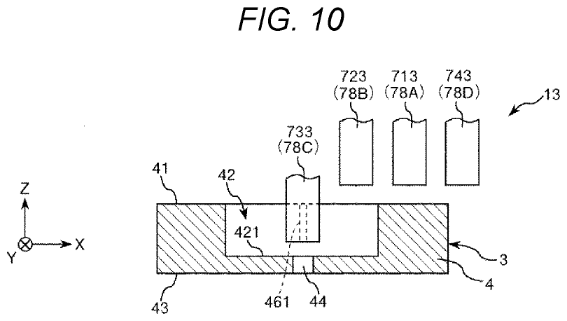

FIGS. 6, 7, 9, and 11 to 14 are schematic horizontal sectional views showing a position detecting operation for the device conveying head in order. FIG. 8 is a schematic partial vertical sectional view of a state shown in FIG. 7. FIG. 10 is a schematic partial vertical sectional view of a state shown in FIG. 9.

As shown in FIG. 6, the position detecting section 3 is in a state “ON” in which the light LS5 is emitted from the first light emitting section 5A and received by the first light receiving section 5B and the light LS6 is emitted from the second light emitting section 6A and received by the second light receiving section 6B. In other words, in the position detecting section 3, both of the light LS5 and the light LS6 are in a transmitted state.

Subsequently, as shown in FIG. 7, the suction nozzle 733, which is a first nozzle of the device conveying head 13, is moved to a position overlapping the center O44 of the position detecting section 3. In other words, as shown in FIG. 8, the suction nozzle 733, which is the first nozzle of the device conveying head 13, is moved to above the upper surface 41 of the position detecting section 3 and right above the through-hole 44. Such a position is detected in advance based on an image captured by the camera 771 and is stored in the control section 800. As shown in FIG. 7, the light LS5 and the light LS6 are still in the transmitted state.

Subsequently, as shown in FIG. 9, the suction nozzle 733 is moved to the Z-direction negative side and inserted into the recess 42 of the position detecting section 3. In other words, as shown in FIG. 10, the suction nozzle 733 is moved downward to a position where the suction nozzle 733 is not in contact with the bottom 421 of the recess 42 of the position detecting section 3. Consequently, the position detecting section 3 is in a state “OFF” in which light reception of the light LS5 in the first light receiving section 5B is blocked by the suction nozzle 733 and light reception of the light LS6 in the second light receiving section 6B is blocked by the suction nozzle 733. In other words, both of the light LS5 and the light LS6 are in a blocked state by the suction nozzle 733.

In the position detection, the suction nozzle 733 starts movement in the X direction and the Y direction from such a position. Consequently, irrespective of whether the suction nozzle 733 moves in the X direction or the Y direction, the suction nozzle 733 can be prevented from colliding with the sidewall section 422, the sidewall section 423, the sidewall section 424, and the sidewall section 425 of the recess 42. When both of the light LS5 and the light LS6 are not in the blocked state by the suction nozzle 733, the position of the suction nozzle 733 is finely adjusted to a position where the light LS5 and the light LS6 are in the blocked state.

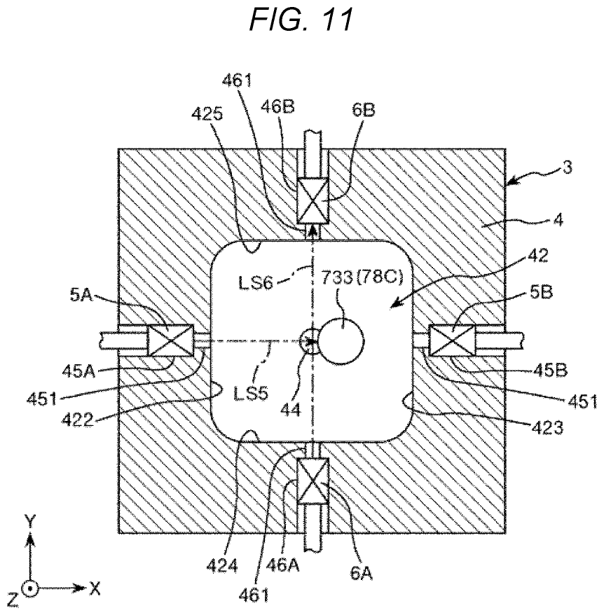

Subsequently, as shown in FIG. 11, the suction nozzle 733 is gradually moved to the X-direction positive side and stopped in a position where the second light receiving section 6B is in the light reception state “ON”. An X coordinate of this position is stored in the control section 800 as a “first X coordinate” of the suction nozzle 733.

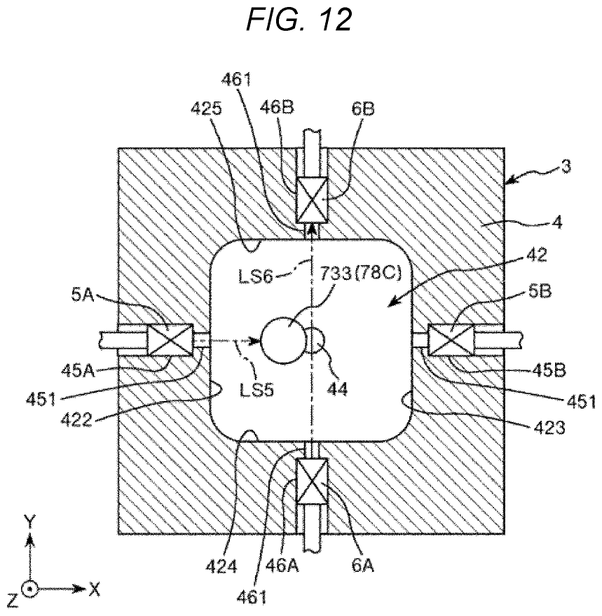

Subsequently, as shown in FIG. 12, the suction nozzle 733 is gradually moved to the X-direction negative side and stopped in a position where the second light receiving section 6B is in the light reception state “ON” again. An X coordinate of this position is stored in the control section 800 as a “second X coordinate” of the suction nozzle 733.

Subsequently, the control section 800 detects or calculates the position of the center between the first X coordinate and the second X coordinate as a “center X coordinate”, which is the center position in the X direction of the suction nozzle 733, and stores the position.

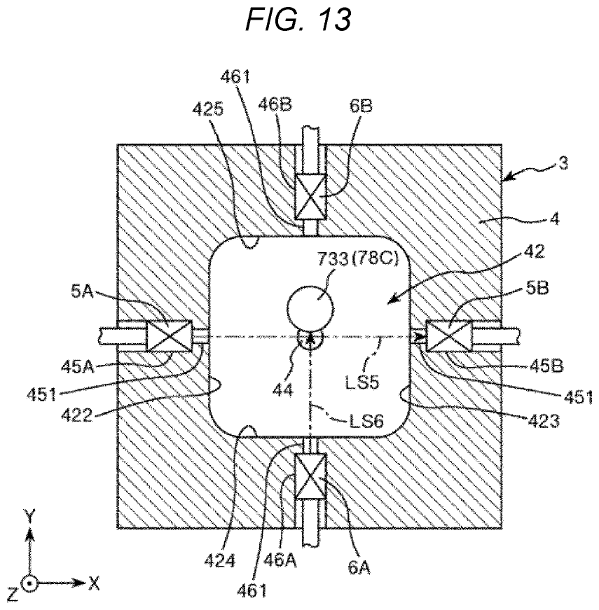

Subsequently, the suction nozzle 733 is returned to the movement start position again. As shown in FIG. 13, the suction nozzle 733 is gradually moved to the Y-direction positive side and stopped in a position where the first light receiving section 5B is in the light reception state “ON”. A Y coordinate of this position is stored in the control section 800 as a “first Y coordinate” of the suction nozzle 733.

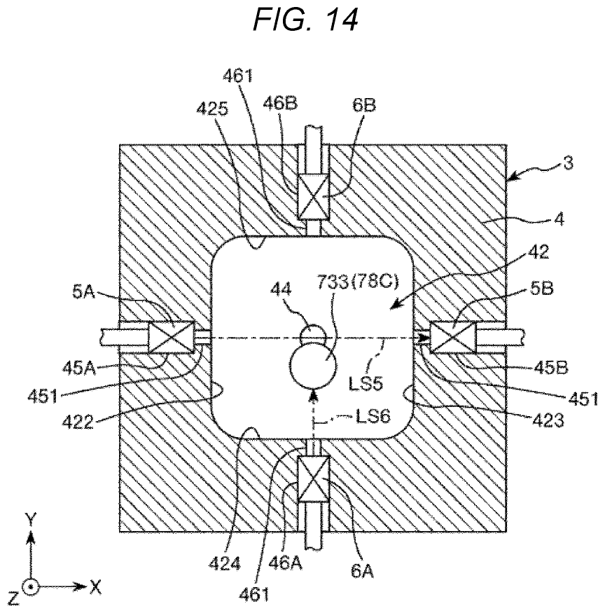

Subsequently, as shown in FIG. 14, the suction nozzle 733 is gradually moved to the Y-direction negative side and stopped in a position where the first light receiving section 5B is in the light reception state “ON” again. A Y coordinate of this position is stored in the control section 800 as a “second Y coordinate” of the suction nozzle 733.

Subsequently, the control section 800 detects or calculates the position of the center between the first Y coordinate and the second Y coordinate as a “center Y coordinate”, which is the center position in the Y direction of the suction nozzle 733, and stores the position.

As explained above, the position detecting section 3 is capable of detecting the center X coordinate, which is the position in the X direction of the suction nozzle 733 of the third holding section 78C, and the center Y coordinate, which is the position in the Y direction of the suction nozzle 733.

The control section 800 can perform, based on the reference position detected by the position detecting section 3 having such a configuration, that is, the center X coordinate and the center Y coordinate of the suction nozzle 733 of the third holding section 78C, position correction at the time when the device conveying head 13 or 20 functioning as the holding section positionally deviates.

### Initial Setting Method

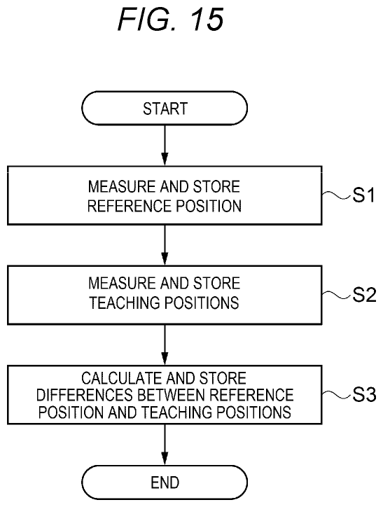

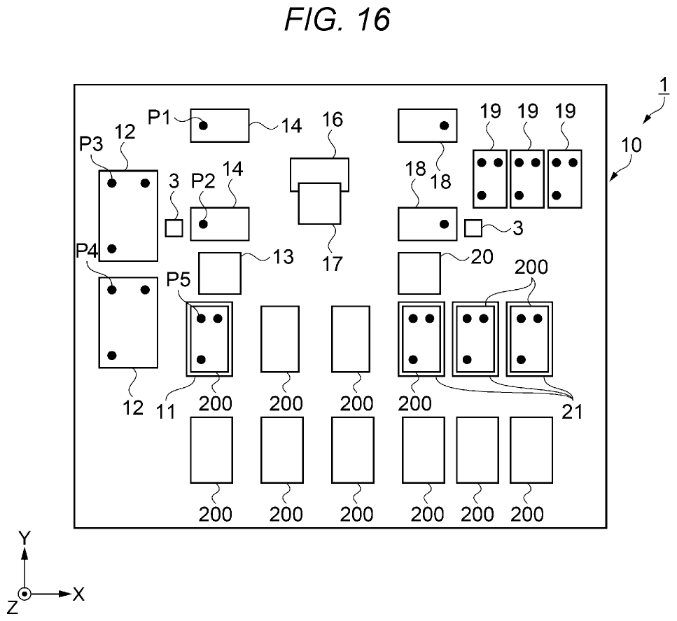

An initial setting method for a reference position of the device conveying head 13 or 20 for conveying the IC device 90, which is the electronic component, and teaching positions serving as operation reference positions for determining operating positions where the IC device 90 is held or placed is explained with reference to FIGS. 15 and 16.

FIG. 15 is a flowchart during initial setting. FIG. 16 is a schematic plan view for explaining the teaching positions. In the following explanation, the initial setting method for the reference position and the teaching positions is explained according to FIG. 15 with reference to FIG. 16.

First, in step S1, the control section 800 matches the suction nozzle 733 of the device conveying head 13 or 20 with the center O44 of the through-hole 44 of the position detection section 3 serving as a reference position of the device conveying head 13 or 20 for conveying the IC device 90 to measure and store an X coordinate and a Y coordinate on the XY plane in a CAD drawing of the electronic component tester 1.

Subsequently, in step S2, the control section 800 measures and stores teaching positions serving as operation reference positions for determining operating positions where the IC device 90, which is the electronic component, is held or placed. The teaching positions are indicated by black points as shown in FIG. 16. The teaching positions are operation reference positions P1 and P2 of the electronic-component mounting sections 14 where the IC device 90 is placed, operation reference positions P3 and P4 of the temperature adjusting positions 12 where the IC device 90 is placed, and an operation reference position P5 of the container mounting section 11 where the IC device 90 is held. In the temperature adjusting sections 12, there are operation reference positions provided on the same X axis as the operation reference positions P3 and P4 and operation reference positions provided on the same Y axis as the operation reference positions P3 and P4. The temperature adjusting sections 12 can accurately match the X axis and the Y axis on a CAD drawing. In the container mounting section 11, as in the temperature adjusting sections 12, there are an operation reference position provided on the same X axis as the operation reference position P5 and an operation reference position provided on the same Y axis as the operation reference position P5.

In measurement of a teaching position, the device conveying head 13 or 20 is moved to above the teaching position. The center of the teaching position and the imaging center of the camera 771 are matched by the camera 771 included in the device conveying head 13 or 20 to measure an X coordinate and a Y coordinate. A distance in the X-axis direction and a distance in the Y-axis direction between the center of the suction nozzle 733 and the imaging center of the camera 771 are subtracted from the measured X coordinate and the measured Y coordinate to measure an X coordinate and a Y coordinate on the XY plane in the CAD drawing of the electronic component tester 1.

Subsequently, in step S3, the control section 800 calculates and stores distances between the X coordinate of the reference position measured in step S1 and X coordinates of the teaching positions measured in step S2 and distances between the Y coordinate of the reference position measured in step S1 and Y coordinates of the teaching positions measured in step S2.

Consequently, the control section 800 ends the initial setting for the reference position and the teaching positions. The operations in steps S1 to S3 explained above are performed in the same manner for a reference position and teaching positions in the device collection region A4.

### Teaching Position Error Detecting Method

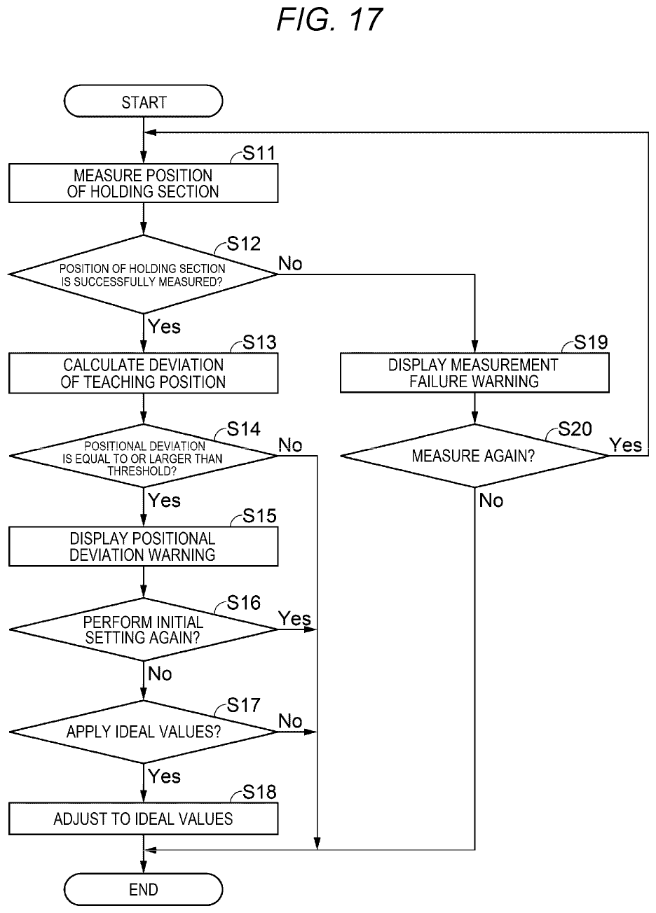

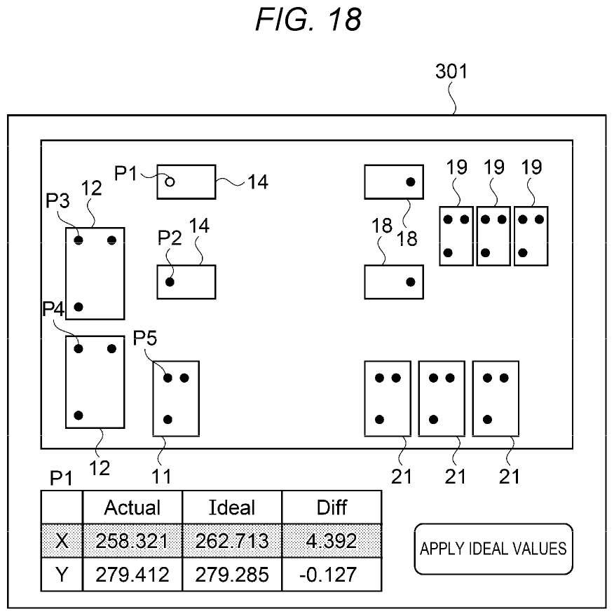

The teaching position error detecting method is explained with reference to FIGS. 17 and 18.

FIG. 17 is a flowchart during teaching position error detection. FIG. 18 is a diagram for explaining a detection result displayed on the display section. In the following explanation, the teaching position error detecting method is explained according to FIG. 17 with reference to FIG. 18.

First, in step S11, the control section 800 measures a reference position of the device conveying head 13 or 20 functioning as the holding section. Specifically, the control section 800 moves the suction nozzle 733 of the device conveying head 13 or 20 to the reference position set in the initial setting, detects, in the position detecting section 3, the position of the suction nozzle 733 of the device conveying head 13 or 20, and stores an X coordinate and a Y coordinate.

Subsequently, in step S12, when the reference position of the device conveying head 13 or 20 is not successfully measured, the control section 800 determines “No”, proceeds to step S19, and displays a warning of “measurement failure” on the display screen 301 functioning as the display section of the monitor 300. Thereafter, in step S20, when the reference position of the device conveying head 13 or 20 is measured again, the control section 800 determines “Yes” and proceeds to step S11. When the reference position of the device conveying head 13 or 20 is not measured again, the control section 800 determines “No” and ends the teaching position error detecting method.

In step S12, when the reference position of the device conveying head 13 or 20 is successfully measured, the control section 800 determines “Yes”, proceeds to step S13, and calculates deviation of a teaching position. Specifically, the control section 800 calculates, based on information concerning the reference position of the device conveying head 13 or 20 detected in step S11, a teaching position serving as an operating position, compares the teaching position and a teaching position stored in advance in the initial setting, and calculates positional deviation between the calculated teaching position and the teaching position stored in advance. The positional deviation calculation means that a distance in any direction is calculated between two points. In this embodiment, a distance in the direction along the X axis and a distance in the direction along the Y axis are respectively calculated. The teaching position serving as the operating position can be calculated by adding the distance in the X-axis direction and the distance in the Y-axis direction stored in step S3 to the reference position coordinate of the device conveying head 13 or 20 measured in step S11.

Subsequently, in step S14, when the positional deviation between the calculated teaching position and the teaching position stored in advance is not equal to or larger than a predetermined value, the control section 800 determines “No” and ends the teaching position error detecting method.

In step S14, when the positional deviation between the calculated teaching position and the teaching position stored in advance is equal to or larger than the predetermined value, the control section 800 determines that the calculated teaching position is abnormal, determines “Yes”, proceeds to step S15, and displays a warning of “positional deviation” on the display screen 301 of the monitor 300. In other words, since a determination result of the control section 800 is displayed, the user can easily confirm an abnormality of the device conveying head 13 or 20. FIG. 18 shows an example of a warning. Disposition positions of the container mounting section 11, the temperature adjusting section 12, and the electronic-component mounting section 14 and teaching positions including the operation reference positions P1 to P5 in a region where a device is supplied and disposition positions of the electronic-component mounting section 18, the tray for collection 19, and the container mounting section 21 and teaching positions in a region where a device is collected are displayed above the display screen 301. A detection result of the operation reference position P1, which is a teaching position, and a calculation result of positional deviation are displayed below the display screen 301. An X coordinate and a Y coordinate of the calculated operation reference position P1 are displayed in an “Actual” field. An X coordinate and a Y coordinate of the operation reference position P1 stored in advance are displayed in an “Ideal” field. Distances between calculated positions and positions stored in advance on the X axis and the Y axis are displayed in a “Diff” field. The X coordinates having the difference equal to or larger than a predetermined value is determined as abnormal and colored and displayed.

Subsequently, in step S16, when the initial setting is performed again, the control section 800 determines “Yes”, ends the teaching position error detecting method, and performs the initial setting explained above again.

In step S16, when the initial setting is not performed again, the control section 800 determines “No” and proceeds to step S17. When the ideal values, which are the teaching positions stored in advance, are not applied, the control section 800 determines “No” and ends the teaching position error detecting method.

In step S17, when the user determines to apply the ideal values and touches “apply ideal values” displayed below the display screen 301, the control section 800 determines “Yes”, proceeds to step S18, and adjusts the X coordinate and the Y coordinate to the ideal values. In other words, the control section 800 adjusts the positional deviation from the reference position of the device conveying head 13 or 20 measured and stored in step S1 and matches the device conveying head 13 or 20 with the reference position measured and stored in step S1. In other words, the control section 800 rewrites the reference position of the device conveying head 13 or 20 to the reference position measured and stored in step S1.

Consequently, the control section 800 ends the teaching position error detecting method.

The teaching position error detection by the position detection of the device conveying head 13 or 20 can be carried out at a predetermined time interval. The predetermined time interval is, for example, every one day, every one week, after elapse of a predetermined time in operation of a device, and after device maintenance. The teaching position error detection can be freely performed according to determination of the user.

As explained above, with the electronic component tester 1 or the electronic component handler 10, the control section 800 calculates the teaching position of the device conveying head 13 or 20 based on the information concerning the reference position of the device conveying head 13 or 20 detected by the position detecting section 3, compares the teaching position with the teaching position stored in advance, and, when the distance between the teaching positions is equal to or larger than the predetermined value, determines that the calculated teaching position is abnormal. Therefore, an abnormality of the teaching position can be detected. Accordingly, by adjusting the detected teaching position to the teaching position stored in advance, it is possible to reduce a mistake in holding the IC device 90 by the device conveying head 13 or 20 and a mistake in conveying the IC device 90 between the container mounting section 11 or 21 and the electronic component mounting section 14 or 18.

A determination result of the control section 800 can be displayed on the display screen 301 of the monitor 300. Therefore, the user can easily confirm an abnormality of the device conveying head 13 or 20.

The reference position of the holding section can be freely detected at the predetermined time interval, for example, after the elapse of the predetermined time or after the device maintenance and according to determination of the user.

### Second Embodiment

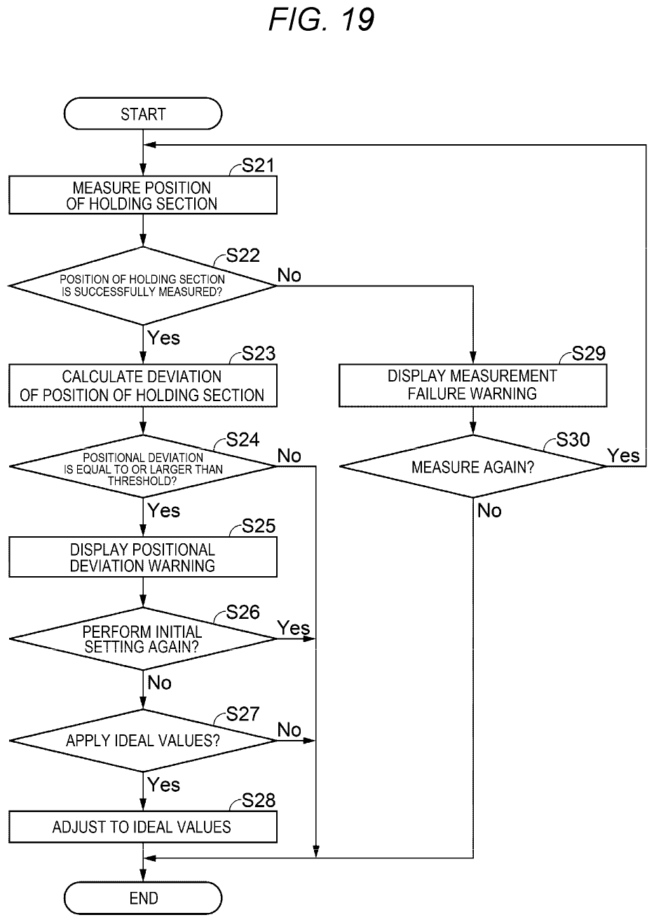

A determining method for an electronic component tester and an electronic component handler according to a second embodiment is explained with reference to FIG. 19.

FIG. 19 is a flowchart during reference position error detection for a holding section according to the second embodiment.

Differences from the first embodiment explained above are mainly explained. Explanation of similarities to the first embodiment is omitted. This embodiment is the same as the first embodiment except that a determining method of determining that a reference position of the device conveying head 13 or 20 functioning as the holding section is abnormal is different.

In the determining method according to this embodiment, as shown in FIG. 19, in step S23, the control section 800 compares the reference position of the device conveying head 13 or 20 detected by the position detecting section 3 and a reference position of the device conveying head 13 or 20 stored in advance and calculates positional deviation.

Subsequently, in step S24, when the positional deviation, which is the distance between the detected reference position of the device conveying head 13 or 20 and the reference position of the device conveying head 13 or 20 stored in advance, is equal to or larger than a predetermined value, the control section 800 determines that the detected reference position of the device conveying head 13 or 20 is abnormal, determines “Yes”, proceeds to step S25, and displays a warning of “positional deviation” on the display screen 301 of the monitor 300.

In step S28, the control section 800 adjusts the detected reference position of the device conveying head 13 or 20 to an ideal value, which is the reference position of the device conveying head 13 or 20 stored in advance. In other words, the control section 800 adjusts the reference position of the device conveying head 13 or 20 to the reference position of the device conveying head 13 or 20 stored in advance.

By adopting this determining method, the control section 800 compares the reference position of the device conveying head 13 or 20 detected by the position detecting section 3 and the reference position of the device conveying head 13 or 20 stored in advance and, when the distance between the reference positions is equal to or larger than the predetermined value, determines that the detected reference position of the device conveying head 13 or 20 is abnormal. Therefore, it is possible to easily detect an abnormality of the reference position of the device conveying head 13 or 20.

By adjusting the detected reference position of the device conveying head 13 or 20 to the reference position of the device conveying head 13 or 20 stored in advance, it is possible to reduce a mistake in holding the IC device 90 by the device conveying head 13 or 20 and a mistake in conveying the IC device 90 between the container mounting section 11 or 21 and the electronic component mounting section 14 or 18.

### Third Embodiment

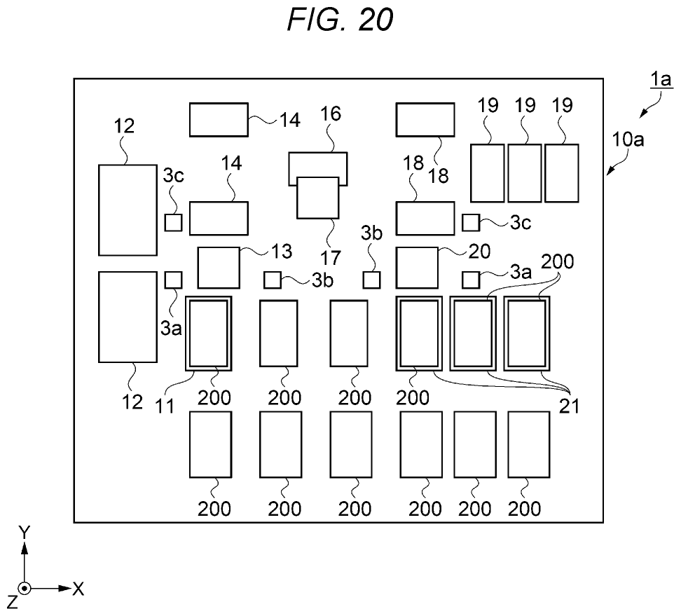

An electronic component tester and an electronic component handler according to a third embodiment are explained with reference to FIG. 20.

FIG. 20 is a schematic plan view showing the configuration of the electronic component tester according to the third embodiment.

Differences from the first embodiment explained above are mainly explained. Explanation of similarities to the first embodiment is omitted. This embodiment is the same as the first embodiment except that the number of set position detecting sections 3a, 3b, and 3c is different.

In an electronic component tester 1a and an electronic component handler 10a according to this embodiment, as shown in FIG. 20, three position detecting sections 3a, 3b, and 3c are disposed between the container mounting section 11 and the electronic-component mounting sections 14. Three position detecting sections 3a, 3b, and 3c are disposed between the electronic-component mounting sections 18 and the container mounting sections 21. The position detecting section 3a functioning as a first detecting section and the position detecting section 3b functioning as a second detecting section are disposed along an X axis serving as a first axis. The position detecting section 3c functioning as a third detecting section is disposed along a Y axis serving as a second axis. Reference positions are respectively provided in the three position detecting sections 3a, 3b, and 3c. XY coordinates of the reference positions are measured and stored in advance.

With this configuration, by moving the device conveying head 13 or 20 to the reference position, detecting the XY coordinates of the device conveying head 13 or 20 in the position detecting sections 3a, 3b, and 3c, and calculating positional deviation between the XY coordinates and the respective reference positions stored in advance, it is also possible to detect tilts with respect to the axes such as deviation of the device conveying head 13 or 20 with respect to the X axis and deviation of the device conveying head 13 or 20 with respect to the Y axis. Accordingly, by adjusting the deviation of the device conveying head 13 or with respect to the X axis and the deviation of the device conveying head 13 or 20 with respect to the Y axis, it is possible to further improve accuracy of holding the IC device 90 by the device conveying head 13 or 20 and accuracy of conveying the IC device 90 between the container mounting section 11 or 21 and the electronic-component mounting section 14 or 18.

Contents derived from the embodiments explained above are described below.

An electronic component handler is an electronic component handler that conveys an electronic component stored in a container to a testing section that tests an electric characteristic of the electronic component, the electronic component handler including: a container mounting section on which the container is mounted; an electronic-component mounting section on which the electronic component before and after the test by the testing section is mounted; a holding section configured to hold the electronic component and convey the electronic component between the container mounting section and the electronic-component mounting section; a detecting section disposed between the container mounting section and the electronic-component mounting section and configured to detect a reference position of the holding section; and a control section configured to control the holding section. The control section calculates, based on information concerning the reference position of the holding section detected by the detecting section, an operating position where the holding section holds or places the electronic component and, when a distance between the calculated operating position and an operating position stored in advance is equal to or larger than a predetermined value, determines that the calculated operating position is abnormal.

With the electronic component handler, the control section calculates the operating position of the holding section based on the information concerning the reference position of the holding section detected by the detecting section, compares the operating position with the operating position stored in advance, and, when the distance between the operating positions is equal to or larger than the predetermined value, determines that the calculated operating position is abnormal. Therefore, it is possible to detect an abnormality of the operating position. Accordingly, by adjusting positional deviation of the operating position, it is possible to reduce a mistake in holding the electronic component by the holding section and a mistake in conveying the electronic component between the container mounting section and the electronic component mounting section.

An electronic component handler is an electronic component handler that conveys an electronic component stored in a container to a testing section that tests an electric characteristic of the electronic component, the electronic component handler including: a container mounting section on which the container is mounted; an electronic-component mounting section on which the electronic component before and after the test by the testing section is mounted; a holding section configured to hold the electronic component and convey the electronic component between the container mounting section and the electronic-component mounting section; a detecting section disposed between the container mounting section and the electronic-component mounting section and configured to detect a reference position of the holding section; and a control section configured to control the holding section. When a distance between the reference position of the holding section detected by the detecting section and a reference position of the holding section stored in advance is equal to or larger than a predetermined value, the control section determines that the detected reference position of the holding section is abnormal.

With the electronic component handler, the control section compares the reference position of the holding section detected by the detecting section and the reference position of the holding section stored in advance and, when the distance between the reference positions is equal to or larger than the predetermined value, determines that the detected reference position of the holding section is abnormal. Therefore, it is possible to detect an abnormality of the reference position of the holding section. Accordingly, by adjusting positional deviation of the reference position of the holding section, it is possible to reduce a mistake in holding the electronic component by the holding section and a mistake in conveying the electronic component between the container mounting section and the electronic component mounting section.

In the electronic component handler, the electronic component handler may include a display section configured to display a determination result of the control section.

With the electronic component handler, the determination result of the control section can be displayed on the display section. Therefore, a user can easily confirm an abnormality of the holding section.

In the electronic component handler, the detecting section may detect the reference position of the holding section at a predetermined time interval.

With the electronic component handler, it is possible to freely detect the reference position of the holding section at a predetermined time interval, for example, after elapse of a predetermined time or after device maintenance or according to determination of the user.

In the electronic component handler, the electronic component handler may adjust the operating position of the holding section based on the distance between the calculated operating position and the stored operating position.

With the electronic component handler, by adjusting the operating position of the holding section based on the distance between the calculated operating position and the operating position stored in advance, it is possible to improve accuracy of holding the electronic component by the holding section and accuracy of conveying the electronic component between the container mounting section and the electronic-component mounting section.

In the electronic component handler, the electronic component handler may adjust the detected reference position of the holding section to the stored reference position of the holding section.

With the electronic component handler, by adjusting the detected reference position of the holding section to the reference position of the holding section stored in advance, it is possible to improve accuracy of holding the electronic component by the holding section and accuracy of conveying the electronic component between the container mounting section and the electronic-component mounting section.

In the electronic component handler, the detecting section may include a first detecting section, a second detecting section, and a third detecting section. When straight lines orthogonal to each other are represented as a first axis and a second axis, the first detecting section and the second detecting section may be disposed along the first axis and the first detecting section and the third detecting section may be disposed along the second axis.

With the electronic component handler, the first detecting section and the second detecting section are disposed along the first axis and the first detecting section and the third detecting section are disposed along the second axis. Therefore, it is also possible to detect a tilt such as deviation of the holding section with respect to the first axis or deviation of the holding section with respect to the second axis. Accordingly, by adjusting the deviation of the holding section with respect to the first axis or the deviation of the holding section with respect to the second axis, it is possible to further improve accuracy of holding the electronic component by the holding section and accuracy of conveying the electronic component between the container mounting section and the electronic-component mounting section.

A determining method is a determining method of determining whether, in an electronic component handler including a container mounting section on which a container is mounted, an electronic-component mounting section on which an electronic component before and after a test is mounted, a holding section configured to hold the electronic component, and a detecting section configured to detect a reference position of the holding section, an operating position where the holding section holds or places the electronic component is a normal position, the determining method including: detecting the reference position of the holding section in the detecting section between the container mounting section and the electronic-component mounting section; calculating an operating position of the holding section based on information concerning the detected reference position of the holding section; comparing the calculated operating position and the operating position stored in advance; and, when a distance between the calculated operating position and the stored operating position is equal to or larger than a predetermined value, determining that the calculated operating position is abnormal.

With the determining method, the operating position of the holding section is calculated based on the information concerning the reference position of the holding section detected by the detecting section, the operating position is compared with the operating position stored in advance, and, when the distance between the operating positions is equal to or larger than the predetermined value, it is determined that the calculated operating position is abnormal. Therefore, it is possible to detect an abnormality of the operating position.

A determining method is a determining method of determining whether, in an electronic component handler including a container mounting section on which a container is mounted, an electronic-component mounting section on which an electronic component before and after a test is mounted, a holding section configured to hold the electronic component, and a detecting section configured to detect a reference position of the holding section, a reference position of the holding section is a normal position, the determining method including: detecting the reference position of the holding section in the detecting section between the container mounting section and the electronic-component mounting section; comparing the detected reference position of the holding section and a reference position of the holding section stored in advance; and, when a distance between the detected reference position of the holding section and the stored reference position of the holding section is equal to or larger than a predetermined value, determining that the detected reference position of the holding section is abnormal.

With the determining method, the reference position of the holding section detected by the detecting section and the reference position of the holding section stored in advance are compared and, when the distance between the reference positions is equal to or larger than the predetermined value, it is determined that the detected reference position of the holding section is abnormal. Therefore, it is possible to detect an abnormality of the reference position of the holding section.

An electronic component tester is an electronic component tester that tests an electronic component stored in a container, the electronic component tester including: a testing section configured to test an electric characteristic of the electronic component; a container mounting section on which the container is mounted; an electronic-component mounting section on which the electronic component before and after the test by the testing section is mounted; a holding section configured to hold the electronic component and convey the electronic component between the container mounting section and the electronic component mounting section; a detecting section disposed between the container mounting section and the electronic-component mounting section and configured to detect a reference position of the holding section; and a control section configured to control the holding section. The control section calculates, based on information concerning the reference position of the holding section detected by the detecting section, an operating position where the holding section holds or places the electronic component and, when a distance between the calculated operating position and an operating position stored in advance is equal to or larger than a predetermined value, determines that the calculated operating position is abnormal.

With the electronic component tester, the control section calculates the operating position of the holding section based on the information concerning the reference position of the holding section detected by the detecting section, compares the operating position of the holding section with the operating position stored in advance, and, when the distance between the operating positions is equal to or larger than the predetermined value, determines that the calculated operating position is abnormal. Therefore, it is possible to detect an abnormality of the operating position. Accordingly, by adjusting deviation of the operating position, it is possible to reduce a mistake in holding the electronic component by the holding section and a mistake in conveying the electronic component between the container mounting section and the electronic component mounting section.

An electronic component tester is an electronic component tester that tests an electronic component stored in a container, the electronic component tester including: a testing section configured to test an electric characteristic of the electronic component; a container mounting section on which the container is mounted; an electronic-component mounting section on which the electronic component before and after the test by the testing section is mounted; a holding section configured to hold the electronic component and convey the electronic component between the container mounting section and the electronic component mounting section; a detecting section disposed between the container mounting section and the electronic-component mounting section and configured to detect a reference position of the holding section; and a control section configured to control the holding section. When a distance between the reference position of the holding section detected by the detecting section and a reference position of the holding section stored in advance is equal to or larger than a predetermined value, the control section determines that the detected reference position of the holding section is abnormal.

With the electronic component tester, the control section compares the reference position of the holding section detected by the detecting section and the reference position of the holding section stored in advance and, when the distance between the reference positions is equal to or larger than the predetermined value, determines that the detected reference position of the holding section is abnormal. Therefore, it is possible to detect an abnormality of the reference position of the holding section. Accordingly, by adjusting deviation of the reference position of the holding section, it is possible to reduce a mistake in holding the electronic component by the holding section and a mistake in conveying the electronic component between the container mounting section and the electronic component mounting section.

What is claimed is:

1. An electronic component handler that conveys an electronic component stored in a container to a testing section that tests an electric characteristic of the electronic component, the electronic component handler comprising:
a container mounting section on which the container is mounted;
an electronic-component mounting section on which the electronic component before and after the test by the testing section is mounted;
a holding section configured to hold the electronic component and convey the electronic component between the container mounting section and the electronic-component mounting section;
a detecting section disposed between the container mounting section and the electronic-component mounting section and configured to detect a reference position of the holding section; and
a control section configured to control the holding section, wherein
the control section calculates, based on information concerning the reference position of the holding section detected by the detecting section, an operating position where the holding section holds or places the electronic component and, when a distance between the calculated operating position and an operating position stored in advance is equal to or larger than a predetermined value, determines that the calculated operating position is abnormal.

2. An electronic component handler that conveys an electronic component stored in a container to a testing section that tests an electric characteristic of the electronic component, the electronic component handler comprising:
a container mounting section on which the container is mounted;
an electronic-component mounting section on which the electronic component before and after the test by the testing section is mounted;
a holding section configured to hold the electronic component and convey the electronic component between the container mounting section and the electronic-component mounting section;
a detecting section disposed between the container mounting section and the electronic-component mounting section and configured to detect a reference position of the holding section; and
a control section configured to control the holding section, wherein
when a distance between the reference position of the holding section detected by the detecting section and a reference position of the holding section stored in advance is equal to or larger than a predetermined value, the control section determines that the detected reference position of the holding section is abnormal.

3. The electronic component handler according to claim 1, further comprising a display section configured to display a determination result of the control section.

4. The electronic component handler according to claim 1, wherein the detecting section detects the reference position of the holding section at a predetermined time interval.

5. The electronic component handler according to claim 1, wherein the electronic component handler adjusts the operating position of the holding section based on the distance between the calculated operating position and the stored operating position.

6. The electronic component handler according to claim 2, wherein the electronic component handler adjusts the detected reference position of the holding section to the stored reference position of the holding section.

7. The electronic component handler according to claim 1, wherein
the detecting section includes a first detecting section, a second detecting section, and a third detecting section, and
when straight lines orthogonal to each other are represented as a first axis and a second axis, the first detecting section and the second detecting section are disposed along the first axis and the first detecting section and the third detecting section are disposed along the second axis.

8. An electronic component tester comprising:
the electronic component handler according to claim 1; and
a testing section configured to test an electric characteristic of the electronic component.

9. An electronic component tester comprising:
the electronic component handler according to claim 2; and
a testing section configured to test an electric characteristic of the electronic component.
